(19) United States
(12) Patent Application Publication
(10) Pub. No.: US 2016/0322476 A1
(43) Pub. Date: Nov. 3, 2016

(54) METHOD OF MANUFACTURING A FIN FIELD EFFECT TRANSISTOR

(71) Applicant: Shanghai Huali Microelectronics Corporation

(72) Inventors: Ningbo Sang, Shanghai (CN); Runling Li, Shanghai (CN); Tianpeng Guan, Shanghai (CN)

(21) Appl. No.: 14/792,579

(22) Filed: Jul. 6, 2015

(30) Foreign Application Priority Data
Apr. 29, 2015 (CN) 201510213551.0

(51) Int. Cl. H01L 29/66; H01L 21/265; H01L 29/51; H01L 21/3213; H01L 29/423; H01L 21/308; H01L 21/311

(52) U.S. Cl. CPC H01L 29/66795; H01L 21/3081; H01L 29/66545; H01L 29/6656; H01L 29/66575; H01L 21/26513; H01L 29/6653; H01L 21/31111; H01L 21/32134; H01L 29/42372; H01L 29/51; H01L 29/517

(57) ABSTRACT

A method of manufacturing a fin field effect transistor is provided. A double spacer protective layer comprising an outer spacer (the first spacer) and an inner spacer (the second spacer) is formed on both sides of the gate, and the thickness of the outer spacer can be adjusted to accurately control the distance between the source/drain ion implantation area and the channel, so as to solve the problem of the hot carrier injection effect caused by the distance being too close between the channel and the source/drain area; in addition, the outer spacers and the inner spacers can be formed by only two film deposition and etching processes without adding a photolithography mask, which can effectively prevent the contact between the gate and the source/drain, so as to substantially reduce the parasitic capacitance.

### CROSS-REFERENCE TO RELATED APPLICATION

This application claims the priority benefit of Chinese Patent Application Serial No. 201510213551.0, filed Apr. 29, 2015. All disclosure of the Chinese application is incorporated herein by reference.

### FIELD OF THE INVENTION

The present invention generally relates to the field of semiconductor manufacturing technology, more particularly, to a method of manufacturing a fin field effect transistor.

### BACKGROUND OF THE INVENTION

In the semiconductor manufacturing industry today, conventional sub-20 nm devices no longer satisfy the Moore's Law, except the three-dimensional 3D) Fin Field Effect Transistor (Fin-FET). The three-dimensional (3D) Fin-FET can be applied to many logics and other applications, and also can be integrated into various semiconductor devices. The Fin-FET device usually includes semiconductor fins with a high aspect ratio, in which a channel and a source/drain area of the device are formed. The Fin-FET device with a higher gate aspect ratio, which could further increase the electrical current flow and reduce the short channel effect.

In the Fin-FET process, there are generally two methods of forming the fins; one conventional method called Fin-first includes, forming fins during the formation of STI (shallow trench isolation) and then performing an ion implantation process and forming a gate; another method is called Fin-last with the application of a Dummy Gate and an RMG (replacement metal gate) Fin-last includes, firstly forming a source/drain area and a Dummy Gate, then etching the silicon substrate while removing the Dummy gate to form fins, and forming an RMG at last.

As compared with the Fin-first process, the Fin-last process has multiple advantages; wherein one of which is that the process before forming the fin in the Fin-last process has many similarities with the conventional planar CMOS process, thus it is easier to be fabricated; another advantage is that the Fin-last process could maximize utilization of the film stress, such as the film in the source/drain area, to improve the channel carrier mobility.

In the conventional Fin-last process, a spacer is formed after the removal of the dummy gate and then to form the RMG. The spacer can control the formation of the RMG and prevent the contact between the source/drain and the gate, so as to avoid the defects such as the high parasitic capacitance caused by only using one gate oxide layer as the barrier layer between the source/drain and the gate in the conventional method. Thus, the Fin-last process substantially reduces the parasitic capacitance.

However, the thickness of the spacer formed by the above process is limited by the width of the channel, thus, it is difficult to use the spacer to control of the distance between the source/drain and the conductive channel. The source/drain too close to the channel would cause a hot carrier effect which is a major failure mechanism in MOS device. Taking the PMOS device as an exemplary example, the holes in the channel are accelerated under a high transverse electric field between the source and drain to form high-energy carriers; then the high-energy carriers collide with silicon lattices to produce ionized electron-hole pairs, and the electrons are collected by the substrate to form a substrate current; most of the holes resulted from the collision flow into the drain, but some holes are injected into the gate under a longitudinal electric field to form a gate current, which is called Hot Carrier Injection. The hot carriers break energy bond in the interface between the silicon substrate and silicon oxide gate oxide, therefore an interface state is formed at the interface between the silicon substrate and the silicon oxide gate oxide, which causes performance degradation of the device such as threshold voltage, transconductance and the current of the linear region/saturation region, thereby result a failure of the MOS device.

Therefore, it is necessary to design a new method for increasing the distance between the conductive channel and the source/drain, so as to minimize the hot carrier effect and optimize the conventional Fin-last process.

### BRIEF SUMMARY OF THE DISCLOSURE

Accordingly, an objective of the present invention is to provide a method of manufacturing a fin field effect transistor, which can increase the distance between the conductive channel and the source/drain and minimize the hot carrier effect.

The method of manufacturing a fin field effect transistor provided by the present invention includes the following steps:

step S01: providing a semiconductor silicon substrate and then depositing a hard mask on the substrate and patterning the hard mask to form a pattern mask of the fin;

step S02: depositing a first film to cover the hard mask and patterning the first film to form a dummy gate;

step S03: depositing a second film to cover the dummy gate, and forming first spacers on the both sides of the dummy gate by performing an anisotropic etching to the second film; then removing the exposed pattern mask to expose the substrate; next, completing ion implantations of LDD and source/drain in the substrate;

step S04: depositing a third film to cover the dummy gate and the first spacers, then planarizing the third film to expose the dummy gate and the first spacers; next removing the dummy gate;

step S05: etching the exposed substrate under the dummy gate to transfer the fin pattern into the substrate, so as to form fins in the substrate;

step S06: depositing a second film again to cover the fins, and forming two second spacers opposite to each other on the inner sides of the first spacers by reactive ion etching; then, depositing a gate oxide layer and a gate on the inner side of the second spacers.

Preferably, the material of the hard mask is silicon nitride, carbon-doped silicon nitride, silicon oxide, or nitrogen-doped silicon oxide.

Preferably, the material of the first film is amorphous carbon, polysilicon or amorphous silicon; the material of the second film is silicon oxide, silicon nitride or combination thereof.

Preferably, the width of the dummy gate is 10˜60 nm.

Preferably, the material of the first film is amorphous carbon, and an O₂ ashing process is used to remove the dummy gate.

Preferably, the width of the first spacer is 5˜20 nm, and the width of the second spacer is 3˜5 nm.

Preferably, the material of the gate oxide layer is silicon oxide, nitrogen-doped silicon oxide or hafnium oxide.

Preferably, the gate material is polysilicon, amorphous silicon or metal.

Preferably, the height of the gate is 30˜80 nm.

Preferably, in the step S03, the exposed pattern mask without the coverage of the dummy gate and the first spacers is removed by a wet etching process using a H₃PO₄ solution or an HF solution with a dilution ratio of 200:1.

The new method according to the present invention can form a double-spacer protective layer comprising an outer spacer (the first spacer) and an inner spacer (the second spacer) on both sides of the gate of the Fin-FET by using conventional semiconductor process, and can accurately control the distance between the source/drain ion implantation area and the channel by adjusting the thickness of the outer spacer, which solve the problem of the hot carrier injection effect caused by the distance being too close between the channel and the source/drain area; in addition, the outer spacers and the inner spacers can be formed by only two film deposition and etching processes without additional photolithography mask, which can effectively prevent the contact between the gate and the source/drain and substantially reduce the parasitic capacitance.

### BRIEF DESCRIPTION OF THE DRAWINGS

FIG. 1 is a flow chart illustrating the method of manufacturing a fin field effect transistor according to one embodiment of the present invention.

FIGS. 2 to 10 are structural schematic diagrams illustrating the steps of manufacturing a fin field effect transistor based on the method of FIG. 1 according to one embodiment of the present invention.

FIGS. 11 to 19 are cross sectional views in the direction perpendicular to the structures shown in FIGS. 2 to 10 respectively.

FIG. 20 is a three-dimensional schematic diagram of the structure shown in FIG. 10 and FIG. 19.

### DETAILED DESCRIPTION OF THE EMBODIMENTS

The embodiments of the present invention will now be described more fully hereinafter with reference to the accompanying drawings.

It is noted that, the drawings are not necessarily to scale, emphasis instead being placed upon illustrating the principles of the present invention.

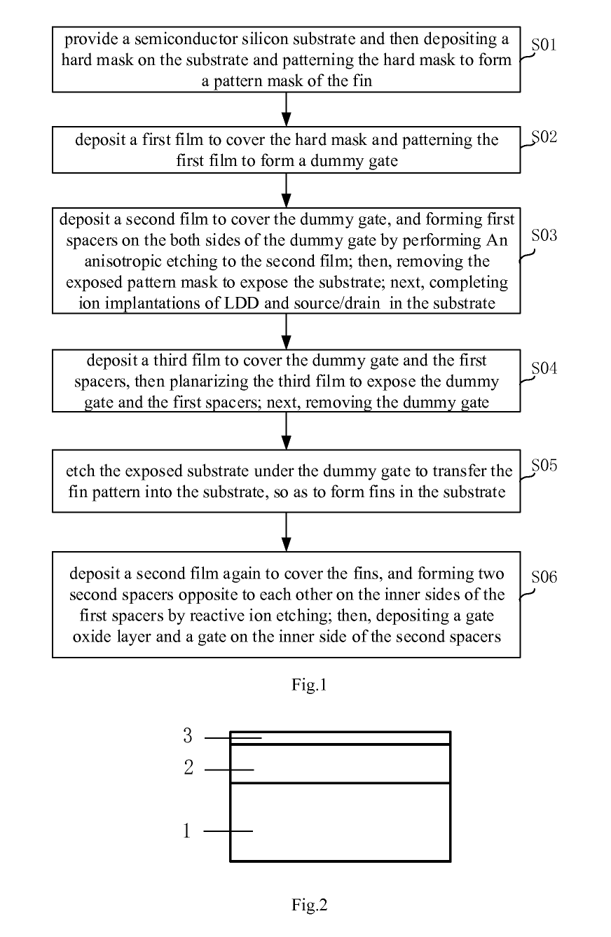

In the following embodiments, referring to FIG. 1, FIG. 1 is a flow chart illustrating the method of manufacturing a fin field effect transistor according to one embodiment of the present invention; referring to FIGS. 2 to 10, FIGS. 11 to 19 and FIG. 20, FIGS. 2 to 10 are structural schematic diagrams illustrating the steps of manufacturing a fin field effect transistor based on the method of FIG. 1 according to one embodiment of the present invention; FIGS. 11 to 19 are cross sectional views in the direction perpendicular to the structures shown in FIGS. 2 to 10 respectively (the cross sectional views along the vertical center axis of the structures shown in FIGS. 2 to 10 respectively); FIG. 20 is a three-dimensional schematic diagram of the structure shown in FIG. 10 and FIG. 19.

As shown in FIG. 1, the method of manufacturing a fin field effect transistor according to one embodiment of the present invention includes the following steps:

step 01: providing a semiconductor silicon substrate and then depositing a hard mask on the substrate and patterning the hard mask to form a pattern mask of the fin.

Referring to FIG. 2 and FIG. 11, the substrate of the present invention is an SOI silicon wafer, an epitaxial silicon wafer or an epitaxial germanium-silicon wafer; in the embodiment, the substrate is an SOI silicon wafer, which including a monocrystalline silicon layer 2 on an insulating buried oxide layer 1. Then, a hard mask is deposited on the monocrystalline silicon layer 2 of the substrate by an exemplary CVD process. As a preferred embodiment, the material of the hard mask is silicon nitride, carbon-doped silicon nitride, silicon oxide, or nitrogen-doped silicon oxide. In one embodiment, a silicon oxide layer with a thickness such as 50 nm is deposited on the substrate by a CVD process as the hard mask. Next, source/drain area pattern and fin pattern are formed by a photolithography process using pattern mask of the fin; then dry etching the hard mask to transfer the fin pattern to the hard mask, so as to form a patterned hard mask 3; or by utilizing high selective etching ratio of the hard mask material and the silicon wafer substrate, the hard mask is etched by photolithography to form the fin pattern. Therefore, in the etching process of this step, the silicon substrate is not etched, that is, the fin pattern is not transferred to the silicon wafer.

step 02: depositing a first film to cover the hard mask and patterning the first film to form a dummy gate;

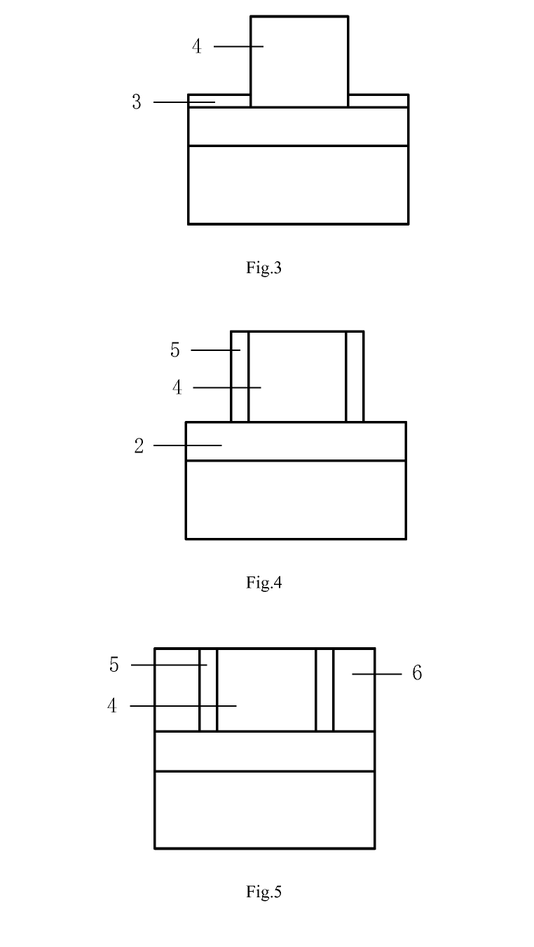

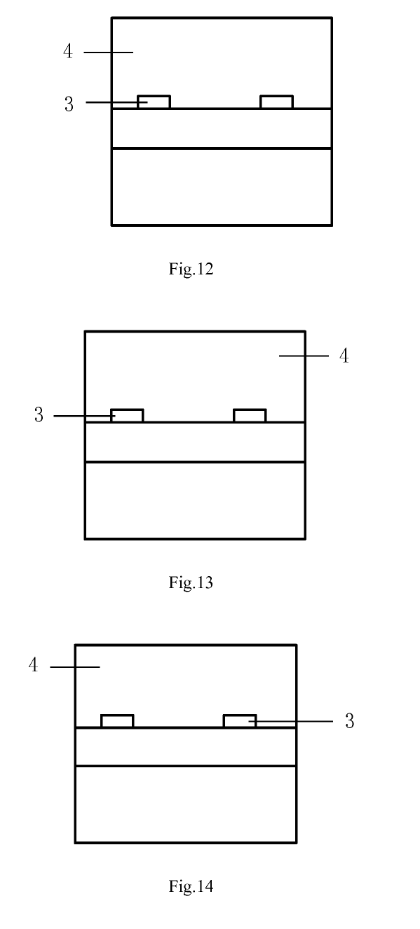

Referring to FIG. 3 and FIG. 12, then, a first film covering the hard mask 3 is formed by a chemical vapor deposition or a sol-gel spin-coating process. As a preferred embodiment, the material of the first film is conventional materials in the semiconductor process, such as amorphous carbon, polysilicon or amorphous silicon; in one embodiment, an amorphous carbon layer is used as the first film, which is deposited by a plasma chemical vapor deposition process; the thickness of the amorphous carbon layer is 150 nm with reactant gases of C₂H₂, N₂ and He. When the flow of N₂ (flux is in a range of 5000 sccm to 10000 sccm) and C₂H₂ (flux is in a range of 500 sccm to 800 sccm) reach a certain threshold and a steady-state, the ratio frequency is been turned on, herein the ratio frequency is a high frequency of 13.56 MHz, the power is in a range of 800 W to 1200 W, and the film begins to be deposited under nitrogen-contained atmosphere and the deposition duration is 30 seconds.

Next, at least one of the silicon nitride, silicon oxide, or SiON is deposited on the first film as a mask layer for etching the first film to form the dummy gate (the figure is not shown); then, a photoresist with a thickness of 200 nm is spin-coated on the mask layer and then a dummy gate pattern is formed by photolithography using a photolithography mask of the gate, wherein developing region is preserved by using a positive photoresist. Then, the photoresist and the mask layer of the dummy gate are removed, so as to form a dummy gate 4. Preferably, the width of the dummy gate 4 is 10˜60 nm. An anisotropic dry etching with a high selective ratio is used in the etching process. In one embodiment, the width of the dummy gate is 14 nm, and then the photoresist is removed to finish the formation of the dummy gate 4.

step S03: depositing a second film to cover the dummy gate, and forming first spacers on the both sides of the dummy gate by performing an anisotropic etching to the second film; then, removing the exposed hard mask to expose the substrate; next, completing ion implantations of LDD and source/drain in the substrate;

Referring to FIG. 4 and FIG. 13, subsequently, the second film is deposited by chemical vapor deposition or atomic layer deposition to cover the dummy gate 4. Then, the outer spacers (the first spacers) 5 are formed on the both sides of the dummy gate 4 by an anisotropic dry etching process using etching gases comprising CF₄ and Ar; wherein the second film has a high step coverage (the ratio of the film thickness on the sidewall of the dummy gate to the film thickness on the top of the dummy gate is greater than 90%). The material of the second film is silicon oxide, silicon nitride or the combination thereof, and the thickness of the deposited second film is 5˜20 nm. In the embodiment, a silicon nitride layer is deposited by an atomic layer deposition process; the thickness of the silicon nitride layer is 5 nm and the step coverage thereof is 100%; then the outer spacers 5 are formed on the both sides of the dummy gate 4 by an anisotropic dry etching process. The etching process to the outer spacers 5 of the dummy gate is required to remove the second film on the top and bottom of the dummy gate 4, while the second film on the both sides of the dummy gate 4 is preserved. The width of the outer spacer (the first spacer) 5 after etching is 5˜20 nm.

Next, the exposed hard mask without the coverage of the dummy gate 4 and the first spacers 5 is removed by a wet etching process using a H₃PO₄ solution or an HF solution with a dilution ratio of 200:1, so as to remove all of the exposed pattern mask to expose the monocrystalline silicon layer 2 of the substrate. Then, the ion implantations of LDD and the source/drain are performed in the monocrystalline silicon layer 2 of the substrate.

step S04: depositing a third film to cover the dummy gate and the first spacers, planarizing the third film to expose the dummy gate and the first spacers; and then removing the dummy gate;

Referring to FIG. 5 and FIG. 14, subsequently, a third film 6 is deposited by an exemplary PECVD process to cover the dummy gate 4 and the first spacers (the outer spacers) 5 formed in the above step. Preferably, the material of the third film 6 is silicon oxide. Then, three films, the third film 6, the dummy gate 4 and the outer spacers 5, are planarized to expose the dummy gate 4 and the first spacers 5 by chemical mechanical planarization (CMP) process. In the embodiment, the thickness of the deposited silicon oxide film is 300 nm, and thickness of the silicon oxide film after the CMP process is 140 nm, wherein the CMP process removed 160 nm of the silicon oxide film and 10 nm of the amorphous carbon dummy gate.

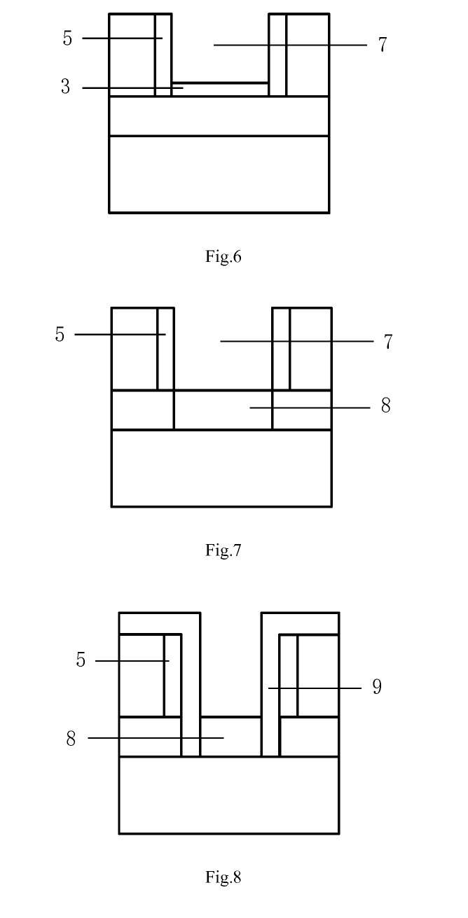

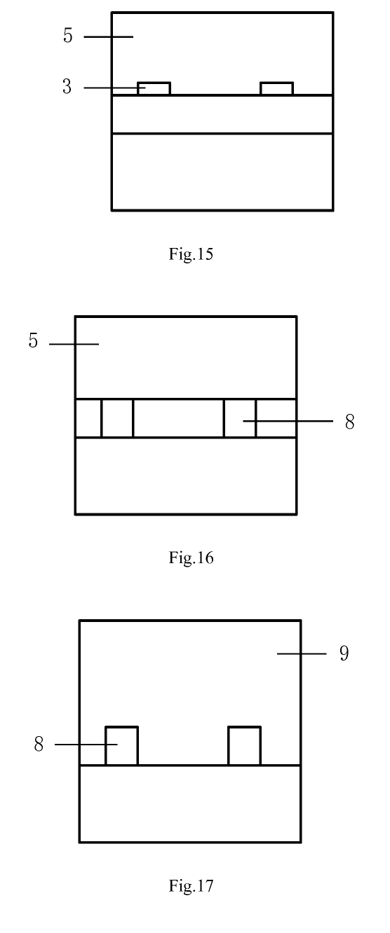

Referring to FIG. 6 and FIG. 15, subsequently, the dummy gate is removed. An O₂ ashing process is used to remove the dummy gate 4, which has a high selective ratio between the fin (the monocrystalline silicon layer 2) and the dummy gate 4, the selective ratio of the dummy gate/fin is greater than 20. In the embodiment, a trench 7 is formed between the outer spacers 5 to expose the pattern mask 3 formed in the aforementioned step.

step S05: etching the exposed substrate under the dummy gate to transfer the fin pattern into the substrate, so as to form fins in the substrate;

Referring to FIG. 7 and FIG. 16, after the removal of the dummy gate in the above step, only the trench 7 made by the outer spacers 5 remains, and the pattern mask 3 formed in the aforementioned step is exposed in the trench 7. Next, the pattern mask 3 and the monocrystalline silicon layer 2 of the substrate under the pattern mask 3 are etched by a dry etching to transfer the fin pattern of the pattern mask 3 to the monocrystalline silicon layer 2 of the substrate, so as to form fins 8. Then, the pattern mask 3 is removed.

step S06: depositing a second film again to cover the fins, and forming two second spacers opposite to each other on the inner sides of the first spacers by reactive ion etching; then, depositing a gate oxide layer and a gate on the inner sides of the second spacers.

Referring to FIG. 8 and FIG. 17, subsequently, a second silicon nitride film 9 is deposited again to cover the fins 8 by atomic layer deposition and the thickness of the silicon nitride film is 3˜5 nm.

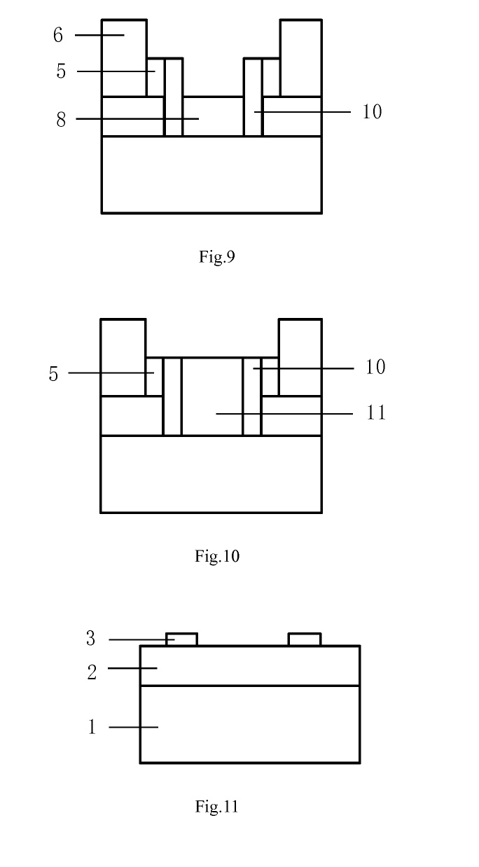

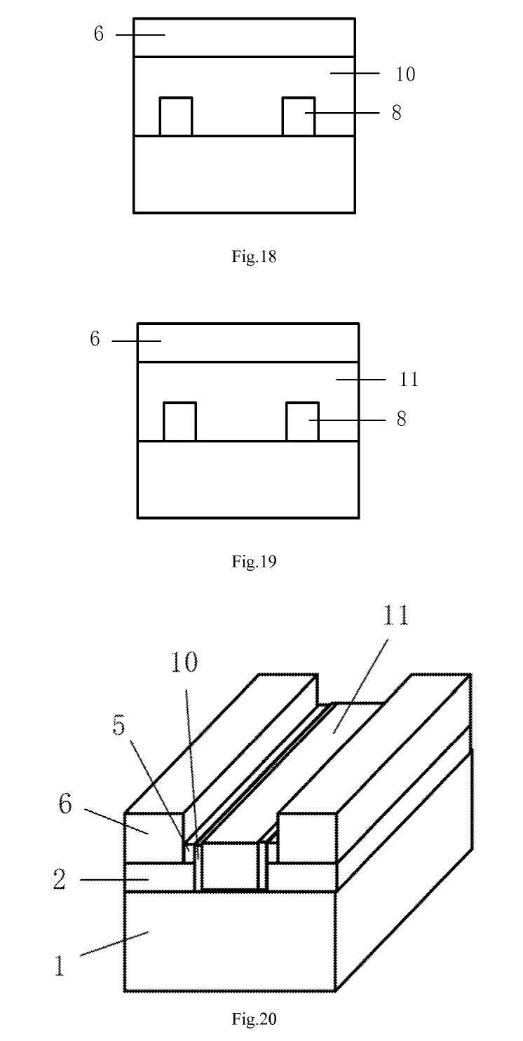

Then, referring to FIG. 9 and FIG. 18, two second silicon nitride spacers 10 (the inner spacers) opposite to each other are formed on the inner sides of the outer spacers (the first spacers) 5 by a reactive ion etching process. The width of the inner spacers (the second spacers) 10 is 3˜5 nm.

Referring to FIG. 10, FIG. 19 and FIG. 20, subsequently, an oxide layer is deposited in the region between the exposed inner spacers as the gate oxide layer (the figure is not shown). The material of the oxide layer is a conventional high dielectric constant material, such as silicon oxide, nitrogen-doped silicon oxide or hafnium oxide, and the thickness of the deposited gate oxide layer is between 8 angstrom and 30 angstrom. Next, the gate 11 is formed by depositing a gate material. The gate material is polysilicon, amorphous silicon, or metal. The height (thickness) of the gate 11 is 30˜80 nm. In the embodiment, the gate oxide layer is formed by an atomic layer deposition process; the material of the gate oxide layer is hafnium oxide and the thickness thereof is 8 angstrom; the gate 11 is a metal gate, such as a laminate of TiN, Al and W. In the FIG. 20, the fins are made from a portion of the monocrystalline silicon layer 2 of the substrate and enclosed by the gate 11 and the inner spacer 10.

The new method according to the present invention can form a double spacer protective layer comprising an outer spacer (the first spacer) and an inner spacer (the second spacer) on both sides of the gate of the Fin-FET by using conventional semiconductor process, and can accurately control the distance between the source/drain ion implantation area and the channel by adjusting the thickness of the outer spacer, so as to solve the problem of the hot carrier injection effect caused by the distance being too close between the channel and the source/drain area; in addition, the outer spacers and the inner spacers can be formed based by only two film deposition and etching processes without additional photolithography mask, which can effectively prevent the contact between the gate and the source/drain, so as to substantially reduce the parasitic capacitance.

While this invention has been particularly shown and described with references to preferred embodiments thereof, if will be understood by those skilled in the art that various changes in form and details may be made herein without departing from the spirit and scope of the invention as defined by the appended claims.

1. A method of manufacturing a fin field effect transistor includes the following steps:
step S01: providing a semiconductor silicon substrate and then depositing a hard mask on the substrate and patterning the hard mask to form a pattern mask of the fin;
step S02: depositing a first film to cover the hard mask and patterning the first film to form a dummy gate;
step S03: depositing a second film to cover the dummy gate, and forming first spacers on the both sides of the dummy gate by performing an anisotropic etching to the second film; then, removing the exposed pattern mask to expose the substrate; next, completing ion implantations of LDD and source/drain in the substrate;
step S04: depositing a third film to cover the dummy gate and the first spacers, then planarizing the third film to expose the dummy gate and the first spacers; next removing the dummy gate;
step S05: etching the exposed substrate under the dummy gate to transfer the fin pattern into the substrate, so as to form fins in the substrate;
step S06: depositing a second film again to cover the fins, and forming two second spacers opposite to each other on the inner sides of the first spacers by reactive ion etching; then, depositing a gate oxide layer and a gate on the inner side of the second spacers.

2. The method of manufacturing a fin field effect transistor according to claim 1, wherein the material of the hard mask is silicon nitride, carbon-doped silicon nitride, silicon oxide, or nitrogen-doped silicon oxide.

3. The method of manufacturing a fin field effect transistor according to claim 1, wherein the material of the first film is amorphous carbon, polysilicon or amorphous silicon; the material of the second film is silicon oxide, silicon nitride or combination thereof.

4. The method of manufacturing a fin field effect transistor according to claim 1, wherein the width of the dummy gate is 10˜60 nm.

5. The method of manufacturing a fin field effect transistor according to claim 3, wherein the material of the first film is amorphous carbon, and an O₂ ashing process is used to remove the dummy gate.

6. The method of manufacturing a fin field effect transistor according to claim 1, wherein the width of the first spacer is 5˜20 nm and the width of the second spacer is 3˜5 nm.

7. The method of manufacturing a fin field effect transistor according to claim 1, wherein the material of the gate oxide layer is silicon oxide, nitrogen-doped silicon oxide or hafnium oxide.

8. The method of manufacturing a fin field effect transistor according to claim 1, wherein the gate material is polysilicon, amorphous silicon or metal.

9. The method of manufacturing a fin field effect transistor according to claim 8, wherein the height of the gate is 30˜80 nm.

10. The method of manufacturing a fin field effect transistor according to claim 1, wherein in the step S03, the exposed pattern mask without the coverage of the dummy gate and the first spacers is removed by a wet etching process using a H₃PO₄ solution or an HF solution with a dilution ratio of 200:1.

11. The method of manufacturing a fin field effect transistor according to claim 1, wherein the height of the gate is 30˜80 nm.
